(19) United States
(12) Patent Application Publication
(10) Pub. No.: US 2010/0156634 A1
(43) Pub. Date: Jun. 24, 2010

(54) Table top contraband sensing apparatus and method

(75) Inventors: R. Kemp Massengill, Leucadia, CA (US); Richard J. McClure, San Diego, CA (US)

Correspondence Address: GERALD W. SPINKS, 546 WESTBURY LANE, GEORGETOWN, TX, 78633, US

(73) Assignee: Intercept Logic, Inc., Escondido, CA (US)

(21) Appl. No.: 12/653,662

(22) Filed: Dec. 16, 2009

Related U.S. Application Data
(60) Provisional application No. 61/203,136, filed on Dec. 19, 2008.
(60) Provisional application No. 61/203,873, filed on Dec. 29, 2008.
(60) Provisional application No. 61/203,930, filed on Dec. 30, 2008.
(60) Provisional application No. 61/206,973, filed on Feb. 6, 2009.

(51) Int. Cl. G08B 21/00; G01R 33/02

(52) U.S. Cl. 340/540; 324/259

(57) ABSTRACT

A table top mounted apparatus and method for detecting contraband, such as paper currency, within a container, where the contraband has a ferromagnetic component. The apparatus includes a DC magnetic field source for inducing a de-magnetization field in any ferromagnetic contraband that may be present within a container, and magnetic sensors for detecting certain characteristic patterns in the “de-mag” field induced by the DC magnetic field source. These certain characteristic field patterns are indicative of contraband arranged in commonly found arrangements of such types of contraband.

### CROSS REFERENCE TO RELATED APPLICATIONS

This application relies upon U.S. Provisional Patent Application No. 61/203,136, filed on Dec. 19, 2008, and entitled “Cash Interceptor Method and Apparatus”; U.S. Provisional Patent Application No. 61/203,873, filed on Dec. 29, 2008, and entitled “Cash Interceptor Method and Apparatus”; U.S. Provisional Patent Application No. 61/203,930, filed on Dec. 30, 2008, and entitled “Cash Interceptor Method and Apparatus”; and U.S. Provisional Patent Application No. 61/206,973, filed on Feb. 6, 2009, and entitled “Cash Interceptor Method and Apparatus.”

### STATEMENT REGARDING FEDERALLY SPONSORED RESEARCH OR DEVELOPMENT

Not Applicable

### BACKGROUND OF THE INVENTION

1. Field of the Invention

This invention is in the field of methods and apparatus used in the detection of illicit shipments of items such as paper currency, weapons, or cell phones.

2. Background Art

The detection of contraband in apparently innocent packages can be a major tool in crime prevention or intervention. For example, hundreds of billions of dollars each year are illegally sent in and out of the United States, with most of this money funding illicit drug activities and/or terrorism. Most of this currency is surreptitiously sent via the United States Post Office, FedEx, UPS, and DHL, although some is hand-carried across borders, or stashed away in checked baggage. Some is even transported in cargo containers. The problem of illegal currency trafficking is not confined to the United States, as most countries have a similar problem. The financing for illegal drug activity, for instance, comes mainly from illegal currency transportation. Finding this illegal currency is a major dilemma. In the United States, the difficulty is compounded, as the use of x-ray scanning technology for United States mail is considered an invasion of privacy.

### BRIEF SUMMARY OF THE INVENTION

The present invention provides a “table top” apparatus and method for finding contraband such as paper currency inside a container, without opening the container. In this application, the term “table top” is used in its broadest generic sense to describe the fact that a container being screened is positioned, and sometimes moved, on the top of a table, a workbench, a counter, or some other similar horizontal work surface. The scanning tool portion of the apparatus can be attached to or positioned beneath the top of a table, or on top of, or alongside the top of a table or other horizontal work surface. Similarly, the method applies to the positioning or moving of a suspect container on the top of a table or other similar work surface, for the purpose of using the apparatus in the detection of contraband, regardless of where the scanning tool portion of the apparatus is mounted. As used herein, the term “container” is also used in its broadest generic sense, and it should be understood to encompass a package, any other shipping container of any kind, a piece of baggage, or any other type of container within which contraband might be concealed. For the sake of simplicity, much of the description of the invention will refer to its use relative to a “package”; it should be understood that these passages also refer to any other type of container.

In the preferred embodiment, the scanning tool is mounted immediately below the work surface, with the work surface being non-ferromagnetic. A detection signal results from positioning of the container near the scanning tool. In the case of the preferred induction coil sensors, movement of the container creates a time varying demag field that can be sensed by induction coil sensors. Sequential scanning of all sides of a package can achieve 3-axis screening of the package for contraband. Since the scanning tool of the present invention is mounted to a fixed structure, the excitation magnetizing source used to magnetize the contraband can be quite large, thereby achieving deep penetration into a container.

In the case of paper currency, the functionality of the invention is based on the fact that modern American currency, and that of many other countries as well, incorporates at least some ferromagnetic material. The present invention includes a scanning tool that incorporates a DC magnetic source, one or more magnetic sensors, and the necessary electronic analysis equipment to process and analyze signals from the sensors. The sensors can be arranged as gradiometers. The magnetic source can be a permanent magnet, a ceramic magnet, a flexible rubber magnet, or one or more DC electromagnetic coils, or some other source of a DC magnetic field. The magnetic source must be large enough to establish a magnetic field that will penetrate well into the interior of a desired package size, with the desired package size being determined by the type of containers that are being subjected to screening in a particular application. This magnetic field establishes a secondary magnetic field, commonly referred to as a “de-mag” field, in the contraband, for example in the ferromagnetic components or portions of the paper currency. Ferromagnetic paper currency that is neatly stacked will have a de-mag field that has a first type of characteristic signal having a uniform and repetitive periodicity that can be thought of as a “bump-bump-bump” signal, either represented as an audible signal or a visible graph. Conversely, ferromagnetic paper currency that is arranged in a disorganized pile will have a de-mag field that has a second type of characteristic signal having a uniform but non-repetitive signal spread over the entire area of the currency pile.

In the case where induction coil sensors are used, the package is moved relative to the scanning tool, so that the DC magnetizing field creates a time-varying de-mag field in the contraband. This occurs regardless of how the contraband is arranged. This time-varying de-mag field can be detected by an induction coil sensor, since movement of the DC magnetizing source simulates the creation of an AC magnetic field. Electronic computation equipment on or associated with the scanning tool analyzes the signals produced by the magnetic sensors, preferably induction coil sensors, to detect the existence of either the periodic uniform field or the non-periodic uniform field discussed above, and to indicate that ferromagnetic contraband is probably present, in either case. Appropriate display screens can be provided for the operator, showing the demag signal received by the sensors. Also, hard-copy printouts can be provided. Visible and audible alarms can also be provided if the characteristic contraband signals are received. Data and alarm outputs can be transmitted to a remote location via the Internet, if desired. Artificial intelligence systems can be employed to analyze the signals and determine the likelihood of contraband in the package, including the use of neural networks and rule based systems.

Although the primary application of the interceptor system of the present invention is for the detection of illicit currency, three other important applications exist. The first is the detection of cell phones. Inside a prison, cell phones defeat some of the purposes of incarceration, and they can be among the biggest problems prison officials face. For example, criminals with cell phones can continue to run their gangs even while locked up. Cell phones are often sent in packages containing 30-50 units, and these are detectable with the interceptor of the present invention. Cell phones can exhibit a periodic de-mag field somewhat similar to stacks of paper currency.

A second additional application for the present invention is the detection of hand-guns, which are increasingly being sent to Mexico from the United States and sold at a great profit, with this profit used to purchase drugs for shipment back to the United States. Handguns can exhibit a periodic de-mag field somewhat similar to stacks of paper currency.

A third additional application of the present invention is as an anti-counterfeiting tool. Since there is no ferromagnetic demag signal emanating from counterfeit currency, the interceptor of the present invention will not trigger, even when the interceptor is rubbed directly on the surface of the currency. This illustrates that the interceptor can give a reliable indication that paper currency is counterfeit.

The novel features of this invention, as well as the invention itself, will be best understood from the attached drawings, taken along with the following description, in which similar reference characters refer to similar parts, and in which:

### BRIEF DESCRIPTION OF THE SEVERAL VIEWS OF THE DRAWINGS

FIG. 1 is a schematic representation of a first embodiment of the apparatus of the present invention;

FIG. 2 is a schematic representation of the magnetizing field generated by the apparatus;

FIG. 3 is a schematic representation of the demag field generated and detected by the apparatus;

FIG. 4 is a schematic representation of a second embodiment of the apparatus of the present invention;

FIG. 5 is a schematic representation of a third embodiment of the apparatus of the present invention;

FIG. 6 is a schematic of a layout of two sets of sensors arranged as gradiometer pairs;

FIG. 7 is a graphical and schematic representation of the signal pattern generated by some types of contraband in a first arrangement, with the present invention;

FIG. 8 is a graphical representation of the signal pattern generated by a second arrangement of contraband, with the present invention; and

FIG. 9 is a graphical and schematic representation of the signal pattern generated by some types of contraband in a third arrangement, with the present invention.

### DETAILED DESCRIPTION OF THE INVENTION

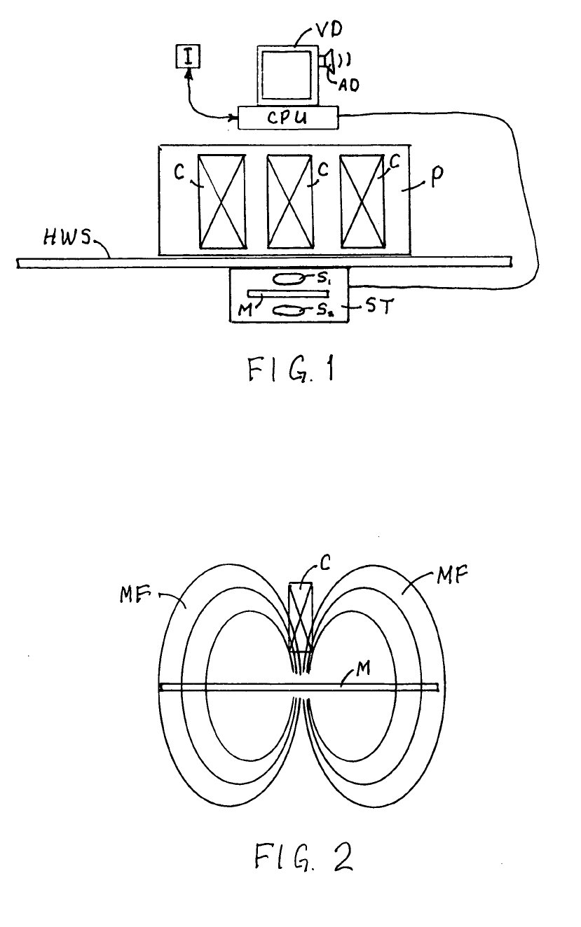

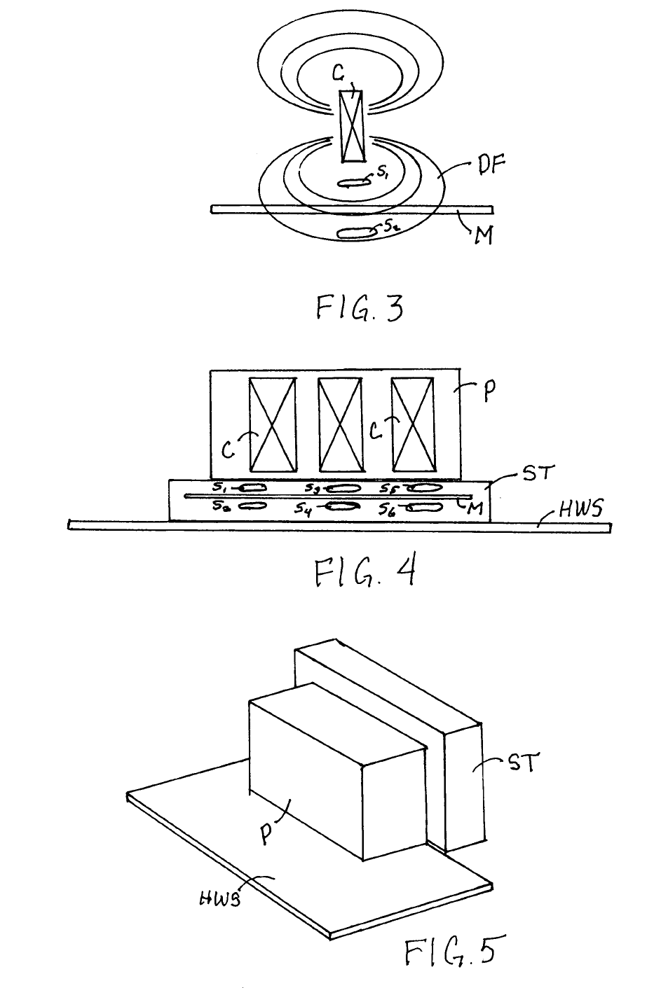

As shown in FIG. 1, a first embodiment of a table top apparatus according to the present invention has a scanning tool ST mounted beneath a horizontal work surface HWS to search for contraband such as paper currency hidden within a box or package P. A magnetizing source M mounted on the scanning tool ST produces a first magnetic field MF, as shown in FIG. 2, which induces magnetization in the hidden contraband or currency C. As shown in FIG. 3, the second, de-magnetization or “de-mag” field DF from this currency or contraband is detected by the sensors S₁, S₂ of the invention, triggering an alarm, preferably with both a visual display VD and an audio display AD. Signal processing and analysis can be performed on the scanning tool ST or in an associated computer CPU.

Boxes, packages, or other containers are screened for contraband by positioning the container P as close to the surface of the scanning tool ST as possible, sequentially scanning one or more sides, and preferably all sides, of the package P.

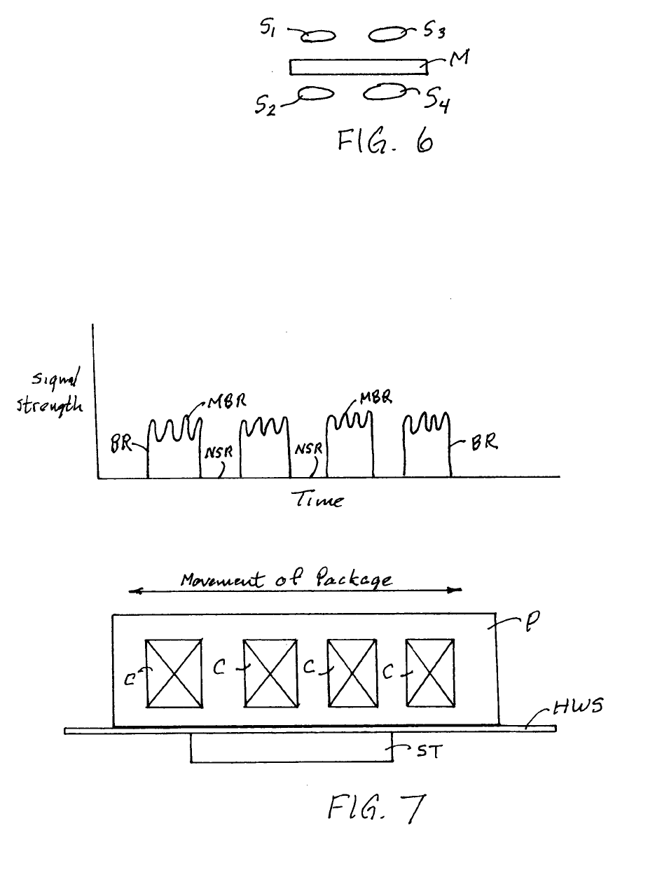

Although in this embodiment, the scanning tool ST is mounted beneath the horizontal work surface HWS, the scanning tool ST could alternatively be placed atop the horizontal work surface HWS, with the package P being positioned directly on the scanning tool ST, as shown in FIG. 4. A single sensor S could be used, or multiple sensors can be arranged in gradiometer pairs, such as S₁/S₂, S₃/S₄, S₅/S₆ could be used, as shown. This embodiment provides some operational flexibility, as the scanning tool ST can be moved more easily from one work surface to another as desired. As another alternative, the scanning tool ST could be mounted beside the horizontal work surface HWS, with the package P being positioned beside and as close as possible to the scanning tool ST, as shown in FIG. 5.

The table top or other horizontal work surface HWS is preferably constructed of a non-ferromagnetic material, such as aluminum. The work surface HWS is also preferably as thin as possible, at least where the scanning tool ST is mounted beneath the work surface HWS, in order to place the package P being screened as close as possible to the sensors S. Importantly, this ensures that any contraband that may be present within the package P will have as large a de-mag field as possible, and that the de-mag signal sensed by the sensors S will be as large as possible. The sensed strength of a de-mag field emanating from a ferromagnetic object is inversely proportional to the distance between the ferromagnetic object and the sensor.

In addition to the elements discussed above, the present invention can include any type of alarm or interconnection that may be appropriate for a given application, and a protective casing. If desired, appropriate readout screens can be provided to show outputs of the sensors or the analysis circuitry, as well as hard-copy printouts of the sensor outputs or the analysis circuitry outputs. These are under computerized direction, either from the circuitry on the scanning tool ST or from the associated computer CPU. Also, if desired, the alarm indices can be connected to the Internet I, which allows distant monitoring of alarm events. In addition, expert systems and artificial intelligence can be employed to process the garnered information, including, but not limited to, neural nets and rule-based systems.

United States currency has little inherent magnetization, typically less than 1 Gauss. Sensor systems which use only an available ambient magnetic field, such as the Earth's field of approximately 0.5 Gauss, cannot detect currency at any distance within packages because of this lack of inherent magnetization in the currency. So, providing an independent magnetic field is required to pre-magnetize the bills to allow detection by the sensor system.

As discussed above, the magnetization source M is utilized to induce magnetization in the currency, with the preferred embodiment of the magnetizing source M being a DC permanent magnet, preferably in the shape of a large, relatively thin, flat plate. Such a plate magnet can be constructed with a plurality of smaller magnetic plates, arranged edge-to-edge. In order to scan packages measuring approximately 20 to 40 inches on a side, for example, the magnetizing source M can be a flat neodymium/iron/boron plate magnet preferably measuring 24 inches by 24 inches, and approximately one quarter inch thick. Such a magnet can be constructed by arranging 24 magnets measuring 6 inches by 4 inches edge to edge, with all plates having their magnet fields arranged parallel to each other. Such an arrangement also minimizes the magnitude of the magnetic field right at the surface of the plate. The contraband interceptor system of the present invention must be able to provide a magnetic field which penetrates as deeply as possible into a package of the desired size, so as large a magnetic source as possible is employed. During use, the surface of the box or package being scanned is preferably oriented parallel to the magnetization source M, which has this relatively thin, flat shape. So, if the scanning tool ST is placed atop or beneath the horizontal work surface HWS, the scanning tool ST should be mounted so that the magnetization source M is oriented parallel to the horizontal work surface HWS, as shown in FIGS. 1 and 4. On the other hand, if the scanning tool ST is placed beside the horizontal work surface HWS, the scanning tool ST should be mounted so that the magnetization source M is oriented orthogonal to the horizontal work surface HWS, as shown in FIG. 5. This orientation allows the deepest penetration of the magnetic field, from a source having this shape, into the box or package.

Various types of DC magnetizing sources also can be employed. A few examples are ceramic magnets, flexible-rubber magnets, and electromagnetic coils producing a DC magnetic field.

Safety concerns must always be considered whenever humans are exposed to magnetic fields. Having a relatively broad, relatively thin permanent magnet source, as described herein, produces a smaller, and therefore safer, field at the surface of the scanning tool ST than would be the case with a relatively thick magnet of relatively limited breadth. At the same time, for a given thickness, a broader permanent magnet source produces a greater field at a given distance than one which is less broad.

Associated with the magnetizing element M is the sensor system S of the present invention, which detects the “demag” magnetic field DF emanating from the magnetized currency as the box or package is moved over the surface of the scanning tool ST.

A single magnetic sensor S can be employed, or, alternatively, an array of magnetic sensors could be used, without employing gradiometer formatting. However, spurious signals from an unrelated distant source can cause annoying false alarms. To provide common-mode rejection of these distant unwanted signals, the sensor elements are preferably arranged in a gradiometer format, consisting of one or more sensor gradiometer pairs. One such embodiment is the configuration shown in FIG. 6, utilizing 2 sensor gradiometer pairs. In this embodiment, sensors S1 and S2 form a gradiometer pair; and sensors S3 and S4 form a gradiometer pair. Another example was shown in FIG. 4, with three gradiometer pairs S₁/S₂, S₃/S₄, S₅/S₆. In the preferred embodiment, however, only one gradiometer pair, consisting of sensors S1 and S2, is utilized, as shown in FIG. 3. Of course, if desired, four or more gradiometer pairs can be utilized. The use of a gradiometer format greatly improves reliability, as it rejects magnetic signals from extraneous irrelevant sources. It is desirable to have the sensors constituting a gradiometer pair spaced as widely as possible, such as 3 to 4 inches apart, as this increases detectability at a distance within the package. The output of the sensors S can be sent to a computer CPU located either on the scanning tool ST or separately, and computer analysis can be employed for processing data.

The preferred embodiment of the present invention employs induction coil sensors, although other sensors may be employed in the non-preferred embodiment, including magnetoresistive sensors, fluxgate sensors, Hall effect sensors, optical sensors, and any other sensors known in the art to be capable of ferromagnetic detection. Non-saturable sensors may also be used. With induction coil sensors, as the package is moved around the surface of the horizontal work surface HWS relative to the DC magnetization source M, the first field created by the magnetization source simulates an AC field, which simulates the creation of an AC de-mag field, which can be sensed by induction coil sensors. Importantly, with induction coil sensors, moving the package faster increases sensitivity, as the strength of the detected signal is related in linear fashion to the speed of movement. Brisk movement of the box or package therefore increases sensitivity. The induction coil sensors are blind to non-moving ferromagnetic objects, which is an advantage if there are ferromagnetic cabinets, etc., in the vicinity of the screening apparatus.

The sensor system S and the DC magnetization source M of the present invention are rigidly secured to the scanning tool ST, in a fixed spatial relationship relative to each other, so that unwanted false-alarm signaling does not result from relative movement between the sensors and the magnetization source. The sensors are also shielded from temperature variations which could cause faulty and inaccurate sensing. In addition to a thermal-insulating protective cover, or as an alternative, the sensor assemblies can be coated liberally with epoxy or another suitable insulating material.

The electronics circuitry of the present invention features low-noise amplifiers, and gold contacts, rather than tin, should be used for increased reliability. Signal digitization places the operation and the data collection under computerized control, which allows for special noise-cancelling techniques and excellent flexibility for signal-display options. The preferred embodiment powers the electronics circuitry with an AC/DC step-down transformer, for reliability.

In the preferred embodiment, the present invention has an alarm with both audio components and visual components. Numerous options can be utilized, including, but not limited to, a multi-tone audio alarm, colored lights (such as green for no detected signal, and red for an alarm), a visual display of signal strength, and other desired graphic and visual displays. Also, if desired, Internet connectivity can be employed for transmitting information to a remote location, and even for remote real-time monitoring of alarm events as they occur. Expert artificial intelligence systems can be employed for automated data interpretation, as mentioned above.

When searching for paper currency, the pattern of the alarm response can give vital clues. American paper currency is not uniformly ferromagnetic, but rather has discrete areas of ferromagnetic material, such as ink, and other areas which are not ferromagnetic. Interestingly, for many currencies, not all of the ink on a particular bill is ferromagnetic.

When scanned with the present invention, ferromagnetic paper currency typically produces one of two distinct signals, or a combination of these two signals: (1) a signal demonstrating periodicity, called herein the “bump/bump/bump” response, corresponding to neatly stacked bills; and, (2) a signal without periodicity, corresponding to currency placed willy-nilly and with random orientation within a package.

If bills are stacked in neat piles as is often done in a suitcase, as the surface of the suitcase, box or package is moved in close proximity to the scanning tool ST, a “bump/bump/bump” type of signal response occurs, as illustrated schematically and graphically in FIG. 7. This signal can be heard by the operator on the audible display, or seen on the visual display in the form of a graph, for example. As the package P moves relative to the scanning tool ST, each “bump” response BR corresponds to a suspicious detected signal such as would emanate from a stack of paper currency C, a handgun, or a cell phone, which is followed by a no-signal response NSR of various dimensions. This NSR dimension can be very small, if stacks of bills are arranged closely together, or larger, if the stacks of bills are separated. The no-signal response NSR would also be seen as the sensor detects gaps between handguns or cell phones. This no-signal response is then followed by another detected “bump” response signal BR, as yet more movement occurs and more currency stacks, guns, or cell phones are detected. These “bump/bump/bump” responses are somewhat akin to a car driving on railroad tracks. Also, with a very sensitive scanning tool system, note the “mini-bump” responses MBR, illustrating that the currency is not uniformly ferromagnetic over its surface, but rather each bill has discrete areas of ferromagnetic ink, and then areas of no ferromagnetic ink. Only when currency is neatly stacked, with each bill in the stack having the same orientation, can predictable and repetitive “mini-bumps” be observed, however.

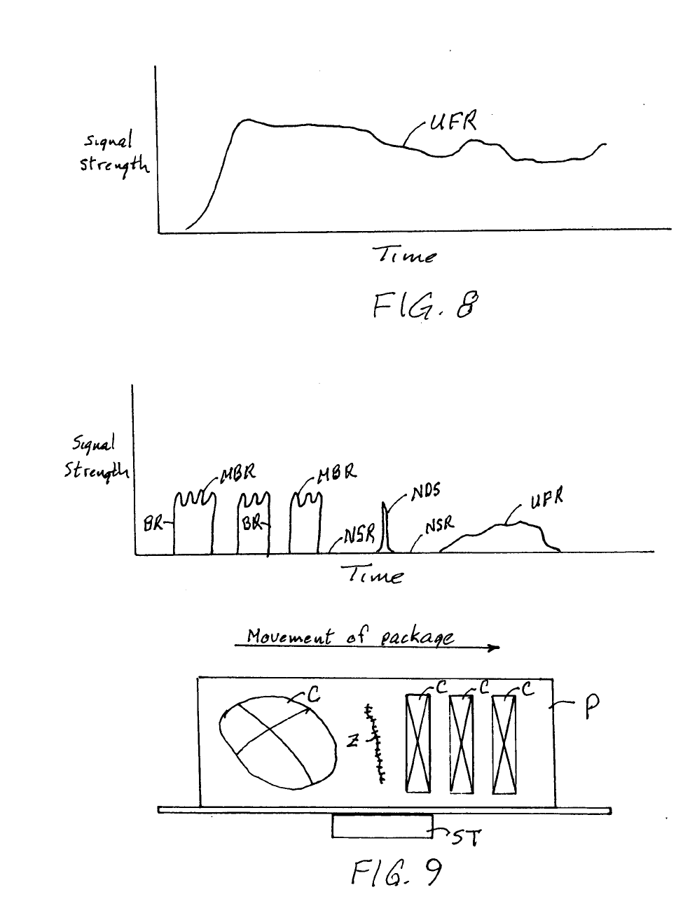

In the real-world, it is known that criminals often tend to stuff money into packages quite randomly, in which case there is no “bump/bump/bump” periodic response, but rather a fairly uniform signal response UFR which persists over an area, such as 6 to 16 inches across, as depicted in FIG. 8. This uniform but non-periodic signal UFR can be thought of as a “blurry” signal. If the package is larger, of course, either of these responses from paper currency can occur in patches, with a lack of signal elsewhere in the package, as shown in FIG. 9. Or, even “non-definitive signals” NDS, which arise from ferromagnetic objects which are other than paper currency, can be noted elsewhere in the package. Non-definitive signals NDS can be defined as small discrete signals which do not fit in one or the other of the two patterns typical of ferromagnetic paper currency. These NDS signals are very unlikely to be currency, but rather are usually caused by a small ferromagnetic object such as a zipper Z. Thus, the present invention provides discrimination between stacks of paper currency, either randomly placed or neatly stacked, producing a relatively broad signal response, and discrete ferromagnetic objects, such as zippers, producing a relatively short blip response.

Packages showing one of the two types of characteristic signal responses discussed above are very likely to contain ferromagnetic paper currency or other contraband, especially as it is less common for a package to contain other ferromagnetic objects which exhibit either: (1) periodicity, and especially, predictable and repetitive periodicity; or, (2) a quite uniform ferromagnetic pattern over a fairly broad area, called herein a “blurry” pattern.

Even rolling bills into the smallest space possible produces a signal over a fairly broad area, assuming that the amount of currency is greater than a token. For example, $5,000 in 50 one-hundred dollar bills constitutes a roll having much more surface area than does a zipper. If a small, discrete ferromagnetic signal were found in one part of the package, and another at a distance of, for instance, 6 inches away, this does not correspond to a pattern consistent with concealed currency. Rather, this pattern is more representative of ferromagnetic objects of no interest, such as a zipper, or a piece of jewelry. Continued use of the present invention, augmented with automated pattern recognition with expert systems including neural nets, will result in more and more reliable detection of concealed contraband in various forms.

The protective covering on the scanning tool and the epoxy coating on the sensors not only provide insurance against damage, but also help to isolate the sensors from air currents and temperature changes which adversely affect sensitivity. The protective casing of the scanning tool is preferably a non-ferromagnetic material, such as plastic or aluminum.

The preferred method of operation of the present invention is to screen all sides of the box or package, positioning the box or package P as close to the surface of the scanning tool ST as possible. Proximity increases sensitivity, as the received signal from ferromagnetic contraband is inversely proportional to the cube of the distance between the currency and the sensors. For example, doubling the distance results in decreasing the received signal strength to one eighth of its initial value. Two axis detection can be achieved by moving the package P to the left and to the right, relative to the operator, (nominally along an x axis) and away from the operator and toward the operator (nominally along a y axis). For all practical purposes, scanning in small circles accomplishes the same goal, i.e., detection along the x and y axes. Moving the package P toward and away from the surface of the scanning tool ST provides detection along the z axis. By scanning all sides of the package, three axis detection is ensured, and, if paper currency is closer to one side than to the others, detectability of this currency is greatly enhanced. This can be important, since it is typically unknown how close, or far away, the hidden currency is from the surface of the package. For instance, a 1 inch box containing paper currency could be concealed within an 8 inch box. It should be noted that the present invention is incapable of reading mail, thereby maintaining privacy, a strict requirement of the United States Post Office.

The use of a horizontal, smooth surface is extremely helpful, especially for screening heavy boxes, as sliding a heavy package on the surface of a smooth table is much easier than lifting its weight. Further, when turning the box over and on its sides, if it is heavy, it need not be lifted but can be pivoted on its surfaces.

In cases where the contraband possesses inherent magnetization, a similar scanning tool could be used for screening without a separate magnetization source M. However, the performance of such an apparatus would be somewhat inferior to the scanning tool ST disclosed herein, and its field of application would be considerably more limited.

While the particular invention as herein shown and disclosed in detail is fully capable of obtaining the objects and providing the advantages hereinbefore stated, it is to be understood that this disclosure is merely illustrative of the presently preferred embodiments of the invention and that no limitations are intended other than as described in the appended claims.

We claim:

1. A method for detecting ferromagnetic contraband hidden within a container, comprising:
providing a scanning tool mounted adjacent a horizontal work surface, said scanning tool including a magnetization source and at least one magnetic sensor;
positioning said container on said work surface in proximity with said scanning tool;
applying a first magnetic field to any contents of said container, said first magnetic field being generated by said magnetization source;
generating a second magnetic field in any ferromagnetic contraband that may be present in said container, said second magnetic field being caused to emanate from said ferromagnetic contraband by said application of said first magnetic field to said ferromagnetic contraband;
sensing said second magnetic field with said at least one magnetic sensor and generating a signal representative of said second magnetic field; and
analyzing said signal to detect a characteristic signal pattern indicating the presence of said ferromagnetic contraband.

2. The method recited in claim 1, wherein said mounting of said scanning tool further comprises mounting said scanning tool beneath said horizontal work surface.

3. The method recited in claim 1, wherein said mounting of said scanning tool further comprises mounting said scanning tool atop said horizontal work surface.

4. The method recited in claim 1, wherein said mounting of said scanning tool further comprises mounting said scanning tool beside said horizontal work surface.

5. The method recited in claim 1, further comprising:
providing at least one induction coil sensor as said magnetic sensor;
moving said scanning tool relative to said container to cause said second magnetic field to vary over time; and
sensing said time varying second magnetic field with said at least one induction coil sensor and generating a time varying signal representative of said time varying second magnetic field.

6. The method recited in claim 5, wherein said detection of said characteristic signal pattern further comprises analyzing said signal to detect a uniform and repetitive periodicity of said signal, said uniform and repetitive signal periodicity indicating the presence of ferromagnetic contraband arranged in a uniform pattern.

7. The method recited in claim 6, wherein said detection of said uniform and repetitive periodicity indicates the presence of ferromagnetic paper currency arranged in a plurality of uniform stacks.

8. The method recited in claim 6, wherein said detection of said uniform and repetitive periodicity indicates the presence of a plurality of firearms arranged in a uniform pattern.

9. The method recited in claim 6, wherein said detection of said uniform and repetitive periodicity indicates the presence of a plurality of cell phones arranged in a uniform pattern.

10. The method recited in claim 5, wherein said detection of said characteristic signal pattern further comprises analyzing said signal to detect a uniform ferromagnetic pattern over a broad area of the container, without periodicity in said signal, said non-periodic uniform signal pattern indicating the presence of ferromagnetic paper currency arranged in a random fashion.

11. The method recited in claim 1, further comprising generating an alarm signal to indicate detection of said characteristic signal pattern indicating the presence of ferromagnetic contraband.

12. The method recited in claim 1, wherein said positioning of said container into proximity with said scanning tool further comprises positioning a plurality of sides of said container in proximity with said scanning tool.

13. The method recited in claim 12, wherein said positioning of said container into proximity with said scanning tool further comprises positioning all sides of said container in proximity with said scanning tool.

14. The method recited in claim 1, wherein said analyzing of said signal comprises employing artificial intelligence to recognize said characteristic signal pattern.

15. The method recited in claim 1, further comprising transmitting data related to said signal via the Internet.

16. An apparatus for detecting ferromagnetic contraband within a container, comprising:
a scanning tool mounted adjacent a horizontal work surface;
a DC magnetization source on said scanning tool;
at least one magnetic sensor on said scanning tool, said magnetic sensor being adapted to sense a second magnetic field from any ferromagnetic contraband that may be present in said container, said second magnetic field being caused to emanate from said ferromagnetic contraband by said application of said first magnetic field to said ferromagnetic contraband;
means for generating a signal representative of said second magnetic field; and
means for analyzing said signal to detect a characteristic signal pattern indicating the presence of ferromagnetic contraband.

17. The apparatus recited in claim 16, wherein said means for analyzing said signal comprises means adapted to detect a uniform and repetitive periodicity of said signal, said uniform and repetitive signal periodicity indicating the presence of ferromagnetic contraband arranged in a uniform pattern.

18. The apparatus recited in claim 16, wherein said means for analyzing said signal comprises means adapted to detect a uniform ferromagnetic pattern over a broad area of the container, without periodicity in said signal, said non-periodic uniform signal pattern indicating the presence of ferromagnetic paper currency arranged in a random fashion.

19. The apparatus recited in claim 16, further comprising an alarm adapted to generate a signal to indicate detection of said characteristic signal pattern.

20. The apparatus recited in claim 16, wherein said DC magnetic source comprises a permanent magnet.

21. The apparatus recited in claim 20, wherein said permanent magnet comprises a ceramic magnet.

22. The apparatus recited in claim 20, wherein said permanent magnet comprises a flexible rubber magnet.

23. The apparatus recited in claim 16, wherein said DC magnetic source comprises at least one DC electromagnetic coil.

24. The apparatus recited in claim 16, wherein said magnetic sensor comprises at least one induction coil sensor.

25. The apparatus recited in claim 16, wherein said at least one magnetic sensor comprises at least two magnetic sensors arranged and connected as a gradiometer pair.
